(19) United States
(12) Patent Application Publication
(10) Pub. No.: US 2019/0208633 A1
(43) Pub. Date: Jul. 4, 2019

(54) SIGNAL TRACE FAN-OUT METHOD FOR DOUBLE-SIDED MOUNTING ON PRINTED CIRCUIT BOARD AND PRINTED CIRCUIT BOARD

(71) Applicant: CELESTICA TECHNOLOGY CONSULTANCY (SHANGHAI) CO. LTD, Shanghai (CN)

(72) Inventors: JIWEI WEN, SHANGHAI (CN); CHENXIA FENG, SHANGHAI (CN); LIANG CHEN, SHANGHAI (CN); LIJUAN QU, SHANGHAI (CN)

(73) Assignee: CELESTICA TECHNOLOGY CONSULTANCY (SHANGHAI) CO. LTD, SHANGHAI (CN)

(21) Appl. No.: 16/234,846

(22) Filed: Dec. 28, 2018

(30) Foreign Application Priority Data
Dec. 29, 2017 (CN) 2017114767667

(51) Int. Cl. H05K 1/11; H05K 1/18; H05K 3/46; H05K 3/42; H05K 3/40

(52) U.S. Cl. CPC H05K 1/116; H05K 1/181; H05K 2201/10189; H05K 3/421; H05K 3/4038; H05K 3/4623

(57) ABSTRACT

The present invention provides a signal trace fan-out method for double-sided mounting on a PCB, including: respectively providing one or more blind vias on the top-layer surface and the bottom-layer surface of a PCB; and fanning out, through each of the blind vias, one or more signal traces of to-be-mounted components on the top-layer surface and the bottom-layer surface of the PCB. The number and positions of the blind vias are set based on the size of routing space when the to-be-mounted component is mounted on the top-layer surface or the bottom-layer surface of the PCB. In a manner of combining the blind vias with through holes, the present invention achieves successful fan-out of the signal traces when QSFP-DD connectors are mounted at same positions on both the top layer and the bottom layer of the PCB, and ensures relatively good signal integrality.

### BACKGROUND OF THE PRESENT INVENTION

### Field of Invention

The present invention relates to the field of electronic circuits, in particular to the technical field of mounting, and specifically to a signal trace fan-out method for double-sided mounting on a printed circuit board (PCB) and a PCB.

### DESCRIPTION OF RELATED ARTS

In the next-generation 400G network switch product, a high-density QSFP-DD connector is used as I/O port. QSFP means Quad Small Form-Factor Pluggable. A transmission rate of a Quad Small Form-Factor Pluggable reaches 40 Gbps. Both the speed and the density of the four-channel pluggable interface are better than those of a four-channel CX4 interface. A small pluggable QSFP connector can satisfy multiple supply protocols of MSA, and can greatly simplify design work of users, including signal integrality of a host connector, squirrel-cage EMI shielding of a module, heat dissipation and a light pipe signal solution. The length of passive and active copper trace assemblies may reach 20 meters. A circular optical trace can improve trace management in an application. Integrating four 10G high-speed messaging channels into one pluggable interconnecting system to achieve four times the port density of the SFP.

To improve I/O port density per unit space, advanced products use a design method in which QSFP-DD connectors are mounted at same positions on both a top surface and a bottom surface of a PCB. However, such design requirement brings difficulties and challenges to fan-out of signal traces of the high-density QSFP-DD connector on the PCB, and integrality at 56 Gbps.

### SUMMARY OF THE PRESENT INVENTION

To resolve the foregoing and other potential technical problems, the present invention provides a signal trace fan-out method for double-sided mounting on a PCB. The signal trace fan-out method for double-sided mounting on a PCB comprises: respectively providing one or more blind vias on the top-layer surface and the bottom-layer surface of a PCB; and fanning out, through each of the blind vias, one or more signal traces of to-be-mounted components on the top-layer surface and the bottom-layer surface of the PCB.

In an embodiment of the present invention, the number and positions of the blind vias are set based on the size of routing space when the to-be-mounted component is mounted on the top-layer surface or the bottom-layer surface of the PCB.

In an embodiment of the present invention, the top-layer surface or the bottom-layer surface of the PCB is provided with one or more vias for fanning out a signal trace of the to-be-mounted component, which is not fanned out through the blind via.

In an embodiment of the present invention, the to-be-mounted component is a connector.

In an embodiment of the present invention, the connector is a QSFP-DD connector.

The present invention further provides a printed circuit board (PCB), one or more blind vias are respectively provided on the top-layer surface and the bottom-layer surface of a PCB; and one or more signal traces of to-be-mounted components on the top-layer surface and the bottom-layer surface of the PCB are fanned out through each of the blind vias.

In an embodiment of the present invention, the number and positions of the blind vias are set based on the size of routing space, when the to-be-mounted component is mounted on the top-layer surface or the bottom-layer surface of the PCB.

In an embodiment of the present invention, the top-layer surface or the bottom-layer surface of the PCB is provided with one or more vias for fanning out a signal trace of the to-be-mounted component, which is not fanned out through the blind via.

In an embodiment of the present invention, the to-be-mounted component is a connector.

In an embodiment of the present invention, the connector is a QSFP-DD connector.

As described above, the signal trace fan-out method for double-sided mounting on a PCB and the PCB of the present invention have the following benefits.

In the present invention, the one or more blind vias are respectively provided on the top-layer surface and the bottom-layer surface of the PCB, the one or more signal traces of the to-be-mounted components on the top-layer surface and the bottom-layer surface of the PCB are fanned out through each of the blind vias. The top-layer surface or the bottom-layer surface of the PCB is provided with one or more vias for fanning out the signal trace of the to-be-mounted component, which is not fanned out through the blind via In a manner of combining the blind vias with through holes with a normal level of PCB manufacturing process, the present invention achieves successful signal traces fan-out when QSFP-DD connectors are mounted at same positions on both the top layer and the bottom layer of a PCB, and ensures relatively good signal integrality.

### BRIEF DESCRIPTION OF THE DRAWINGS

To describe the technical solutions of the embodiment of the present invention more clearly, the following briefly describes the accompanying drawings required for the embodiment. Apparently, the accompanying drawings in the following show merely an embodiment of the present invention, and a person of ordinary skill in the art may still derive other drawings from these accompanying drawings without creative efforts.

FIG. 1 is a schematic flow chart of a signal trace fan-out method for double-sided mounting on a PCB of the present invention.

FIG. 2 is a schematic flow chart of a preferred signal trace fan-out method for double-sided mounting on a PCB of the present invention.

FIG. 3 is a diagram of an example of providing a via and a blind via on a top layer of a PCB of the present invention.

FIG. 4 is a diagram of an example of providing a via and a blind via on a bottom layer of a PCB of the present invention.

Description of reference numerals:

| | |
|---|---|
| 100 | PCB; |
| 110 | Via; |
| 120 | Blind via; and |
| S110 to S130 | Steps. |

### DETAILED DESCRIPTION OF THE PREFERRED EMBODIMENTS

The embodiments of the present invention will be described through specific embodiments in the following. One skilled in the art can easily understand other advantages and effects of the present invention according to contents disclosed by the description. The present invention can also be implemented or applied through other different specific embodiments. Various modifications or changes can also be made to all details in the description based on different points of view and applications without departing from the spirit of the present invention. It needs to be stated that the following embodiments and the features in the embodiments can be combined with one another under the situation of no conflict.

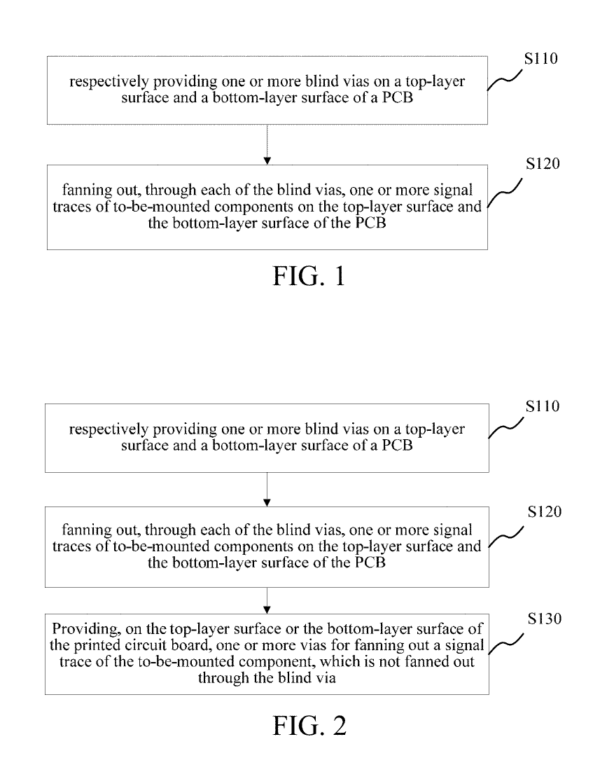

Referring to FIG. 1 to FIG. 4, it should be noted that structures, scales, and sizes illustrated in the accompanying drawings of this specification in cooperation with the contents disclosed in this specification are all used for those skilled in the art understanding and reading, and not intended to limit conditions for implementing the present invention, and therefore do not have essential technical meanings. Any modification of the structures, changes in the scale relationship, or adjustment of the sizes shall fall within the scope that can be covered by the technical contents disclosed in the present invention without affecting the efficacy and the purpose that can be achieved by the present invention .Meanwhile, terms such as “up”, “down”, “left”, “right”, “middle” and “one” quoted in this specification are also used for brief description, and are not intended to limit the scope that can be implemented by the present invention. Changes or adjustments of relative relationships of the terms should be considered within the scope that can be implemented by the present invention if no essential technical content is changed.

An objective of the present embodiment is to provide a signal trace fan-out method for double-sided mounting on a PCB and a PCB, to resolve a problem in the prior art that QSFP-DD connectors cannot be mounted at same positions on both a top surface and a bottom surface of a PCB.

The following describes the principles and implementation modes of a signal trace fan-out method for double-sided mounting on a PCB and a PCB consistent with the present invention in detail, so that those skilled in the art can understand the signal trace fan-out method for double-sided mounting on a PCB and the PCB of the present invention without creative efforts.

As shown in FIG. 1, the present embodiment provides a signal trace fan-out method for double-sided mounting on a PCB, comprising:

step S110: respectively providing one or more blind vias on the top-layer surface and the bottom-layer surface of a PCB; and step S120: fanning out, through each of the blind vias, one or more signal traces of to-be-mounted components on the top-layer surface and the bottom-layer surface of the PCB.

In the present embodiment, as shown in FIG. 2, the signal trace fan-out method for double-sided mounting on a PCB comprises: step S130: the top-layer surface or the bottom-layer surface of the PCB is provided with one or more vias for fanning out a signal trace of the to-be-mounted component, which is not fanned out through the blind via.

The following describes the step S110 to the step S130 in the signal trace fan-out method for double-sided mounting on a PCB in the present embodiment in detail.

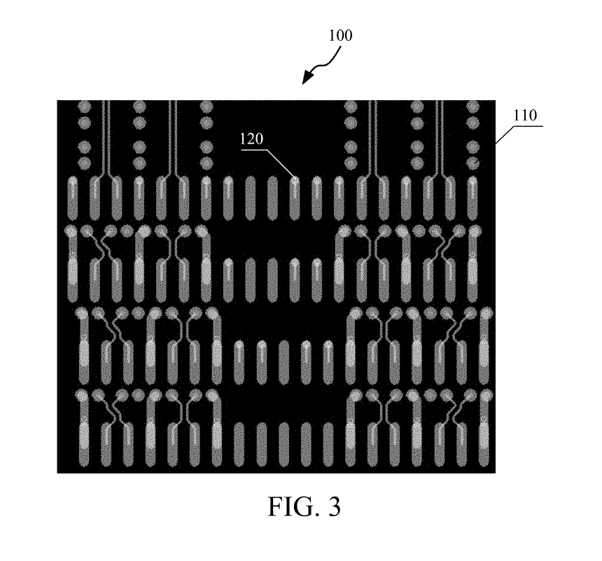

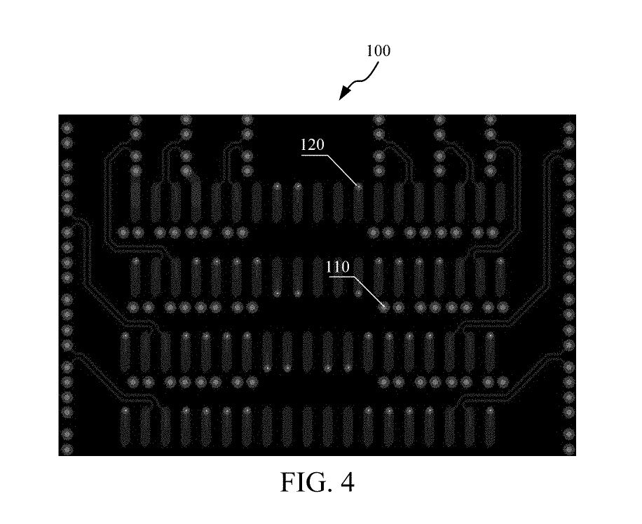

In step S110, as shown in FIG. 3 and FIG. 4, one or more blind vias 120 are respectively provided on the top-layer surface and the bottom-layer surface of a PCB 100.

The blind via 120 can only be seen on the top layer or the bottom layer of the PCB 100, and cannot be seen on the other layer. That is, the blind via 120 is drilled from a surface, but is not drilled through all layers. For example, in a four-layer PCB, the blind via 120 may be only from the first layer to the second layer, or from the fourth layer to the third layer. An advantage of the blind via 120 is that the first layer and the second layer are turned on without affecting routing of the third layer and the fourth layer. However the blind via 120 generally needs a laser drilling machine to drill. The blind via 120 is applied to communication between a surface layer and one or more inner layers. In short, only one surface of the blind via 120 may be seen, and the other surface is in the PCB 100. The blind via 120 is generally applied to a PCB board of four or more layers.

In step S120, one or more signal traces of to-be-mounted components on the top-layer surface and the bottom-layer surface of the PCB 100 are fanned out through each of the blind vias 120.

In the present embodiment, the to-be-mounted component is a connector. Preferably, in the present embodiment, the connector is a QSFP-DD connector.

Since the one or more signal traces of the QSFP-DD connector on the top-layer surface of the PCB 100 are fanned out through the blind via 120, the one or more signal traces of the QSFP-DD connector on the bottom-layer surface of the PCB 100 are also fanned out through the blind via 120, and the blind via 120 on the top-layer or the bottom-layer surface of the PCB 100 do not affect each other. Therefore, the QSFP-DD connectors may be mounted at same positions on both a top layer and a bottom layer of the PCB, and the blind vias 120 may successfully fan out the signal traces when the QSFP-DD connectors may be mounted at the same positions on both the top layer and the bottom layer of the PCB, and relatively good signal integrality is ensured.

Wherein, in the present embodiment, the number and positions of the blind holes 120 are set based on the size of routing space used when the to-be-mounted component is mounted on the top-layer surface or the bottom-layer surface of the PCB 100.

For example, the blind hole 120 is used to fan out a signal trace on inner side of the connector, which cannot be fanned out by using a through hole due to insufficiency of the routing space in the area.

That is, the number and the positions of the blind holes 120 may be adjusted based on routing of the connector, and one or more blind holes 120 may be set at a position where the routing space is insufficient or the via 110 cannot be used for routing.

Wherein, the positions of the blind holes 120 on the top-layer surface or the bottom-layer surface of the PCB 100 may be oppositely disposed on a same vertical line, or may be disposed in a staggering manner, thereby greatly saving the routing space.

In step S130, as shown in FIG. 3 and FIG. 4, the top-layer surface or the bottom-layer surface of the PCB 100 is provided with one or more vias 110 for fanning out a signal trace of the to-be-mounted component that is not fanned out through the blind hole 120.

The via 110 is also referred to as a through hole, and is opened from the top layer to the bottom layer of the PCB 100. For example, in the four-layer PCB, the via 110 runs through the first to fourth layers. The via 110 is mainly classified into two types: a Plating Through Hole (PTH), having copper on a hole wall, generally a VIA PAD and a DIP PAD; and a Non Plating Through Hole (NPTH), having no copper on a hole wall, generally a positioning hole and a screw hole.

For example, the blind hole 120 is used to fan out the signal trace on the inner side of the connector, which cannot be fanned out by using the through hole due to the insufficiency of the routing space in the area. At other positions, a signal trace may be fanned out using the via 110. In a manner of combining the blind holes 120 with the through holes, at a normal level of PCB manufacturing process, the present invention achieves successful fan-out of the signal traces when the QSFP-DD connectors are mounted at same positions on both a top layer and a bottom layer of the PCB, and ensures the relatively good signal integrality.

The embodiment of the present invention further provides a PCB 100, as shown in FIG. 3 and FIG. 4. One or more blind holes 120 are respectively provided on the top-layer surface and the bottom-layer surface of the PCB 100; and one or more signal traces of to-be-mounted components on the top-layer surface and the bottom-layer surface of the PCB 100 are fanned out through each of the blind holes 120.

The blind via 120 can only be seen a top layer or a bottom layer of the PCB 100, and cannot be seen on the other layer. That is, the blind via 120 is drilled from a surface, but is not drilled through all layers. For example, in a four-layer PCB, the blind via 120 may be only from the first layer to the second layer, or from the fourth layer to the third layer. An advantage of the blind via 120 is that the first layer and the second layer are turned on without affecting routing of the third layer and the fourth layer. However the blind via 120 generally needs a laser drilling machine to drill. The blind via 120 is applied to communication between a surface layer and one or more inner layers. In short, the blind via 120 may be seen one surface, and the other surface is in the PCB 100. The blind via 120 is generally applied to a PCB board of four or more layers.

In the present embodiment, the to-be-mounted component is a connector. Preferably, the connector is a QSFP-DD connector.

Since the one or more signal traces of the QSFP-DD connector on the top-layer surface of the PCB 100 are fanned out through the blind via 120, the one or more signal traces of the QSFP-DD connector on the bottom-layer surface of the PCB 100 are also fanned out through the blind via 120, and the blind via 120 on the top-layer surface of the PCB 100 and the blind via 120 on the bottom-layer surface of the PCB 100 do not affect each other. Therefore, the QSFP-DD connectors may be mounted at same positions on both a top layer and a bottom layer of the PCB, and the blind vias 120 may successfully fan out the signal traces when the QSFP-DD connectors may be mounted at the same positions on both the top layer and the bottom layer of the PCB, and relatively good signal integrality is ensured.

Wherein, in the present embodiment, as shown in FIG. 3 and FIG. 4, the number and positions of the blind holes 120 are based on the size of routing space used when the to-be-mounted component is mounted on the top-layer surface or the bottom-layer surface of the PCB 100.

For example, the blind hole 120 is used to fan out a signal trace on the inner side of the connector, which cannot be fanned out by using a through hole due to insufficiency of the routing space in the area.

That is, the number and the positions of the blind holes 120 may be adjusted based on routing of the connector, and one or more blind holes 120 may be set at a position where the routing space is insufficient or the via 110 cannot be used for routing.

Wherein, the positions of the blind holes 120 on the top-layer surface or the bottom-layer surface of the PCB may be oppositely disposed on a same vertical line, or may be disposed in a staggering manner, thereby greatly saving the routing space.

In this embodiment, as shown in FIG. 3 and FIG. 4, the top-layer surface or the bottom-layer surface of the PCB 100 is provided with one or more vias 110 for fanning out signal traces of the to-be-mounted component that is not fanned out through the blind hole 120.

The via 110 is also referred to as a through hole, and is opened from the top layer to the bottom layer of the PCB. For example, in the four-layer PCB, the via 110 runs through the first to fourth layers. The via 110 is mainly classified into two types: a PTH, having copper on a hole wall, generally a VIA PAD and a DIP PAD; and an NPTH, having no copper on a hole wall, generally a positioning hole and a screw hole.

For example, the blind hole 120 is used to fan out the signal trace on the inner side of the connector, which cannot be fanned out by using the through hole due to the insufficiency of the routing space in the area. At other positions, a signal trace may be fanned out using the via 110. In a manner of combining the blind holes 120 with the through holes, at a normal level of PCB manufacturing process, the present invention achieves successful fan-out of the signal traces when the QSFP-DD connectors are mounted at same positions on both a top layer and a bottom layer of the PCB, and ensures the relatively good signal integrality.

In conclusion, in the present invention, the one or more blind vias are respectively provided on the top-layer surface and the bottom-layer surface of the PCB, the one or more signal traces of the to-be-mounted components on the top-layer surface and the bottom-layer surface of the PCB are fanned out through each of the blind vias, and the signal trace of the to-be-mounted components that is not fanned out through the blind vias is fanned out through the one or more vias. In a manner of combining the blind vias with the through holes, at the normal level of the PCB manufacturing process, the present invention achieves successful fan-out of the signal traces when QSFP-DD connectors are mounted at same positions on both the top layer and the bottom layer of the PCB, and ensures relatively good signal integrality. Therefore, the present invention effectively overcomes various disadvantages in the prior art, and has a high industrial utilization value.

The above-described embodiment merely illustrates the principles and effects of the present invention, but is not intended to limit the present invention. Any person skilled in the art can modify or change the above embodiment without departing from the spirit and scope of the present invention. Therefore, all equivalent modifications or changes made by persons of ordinary skill in the art without departing from the spirit and technical thought disclosed in the present invention shall still be covered by the claims of the present disclosure.

What is claimed is:

1. A signal trace fan-out method for double-sided mounting on a printed circuit board (PCB), comprising:
respectively providing one or more blind vias on a top-layer surface and a bottom-layer surface of a PCB; and
fanning out, through each of the blind vias, one or more signal traces of to-be-mounted components on the top-layer surface and the bottom-layer surface of the PCB.

2. The signal trace fan-out method for double-sided mounting on a PCB as in claim 1, wherein the number and positions of the blind vias are set based on the size of routing space when the to-be-mounted component is mounted on the top-layer surface or the bottom-layer surface of the PCB.

3. The signal trace fan-out method for double-sided mounting on a PCB as in claim 1, wherein the top-layer surface or the bottom-layer surface of the PCB is provided with one or more vias for fanning out a signal trace of the to-be-mounted component, which is not fanned out through the blind via.

4. The signal trace fan-out method for double-sided mounting on a PCB as in claim 1, wherein the to-be-mounted component is a connector.

5. The signal trace fan-out method for double-sided mounting on a PCB as in claim 4, wherein the connector is a QSFP-DD connector.

6. The signal trace fan-out method for double-sided mounting on a PCB as in claim 2, wherein the to-be-mounted component is a connector.

7. The signal trace fan-out method for double-sided mounting on a PCB as in claim 3, wherein the to-be-mounted component is a connector.

8. A printed circuit board (PCB), wherein
one or more blind vias are respectively provided on a top-layer surface and a bottom-layer surface of a PCB; and
one or more signal traces of to-be-mounted components on the top-layer surface and the bottom-layer surface of the PCB are fanned out through each of the blind vias.

9. The PCB as in claim 8, wherein the number and positions of the blind vias are set based on the size of routing space, when the to-be-mounted component is mounted on the top-layer surface or the bottom-layer surface of the PCB.

10. The PCB as in claim 8, wherein the top-layer surface or the bottom-layer surface of the PCB is provided with one or more vias for fanning out a signal trace of the to-be-mounted component, which is not fanned out through the blind via.

11. The PCB as in claim 8, wherein the to-be-mounted component is a connector.

12. The PCB as in claim 11, wherein the connector is a QSFP-DD connector.

13. The PCB as in claim 9, wherein the to-be-mounted component is a connector.

14. The PCB as in claim 10, wherein the to-be-mounted component is a connector.
